(19) United States
(12) Patent Application Publication
(10) Pub. No.: US 2013/0248970 A1
(43) Pub. Date: Sep. 26, 2013

(54) NONVOLATILE SEMICONDUCTOR STORAGE DEVICE AND METHOD OF MANUFACTURING THE SAME

(71) Applicant: KABUSHIKI KAISHA TOSHIBA, Tokyo (JP)

(72) Inventors: Naoki KAI, Kuwana (JP); Satoshi Nagashima, Yokkaichi (JP)

(73) Assignee: KABUSHIKI KAISHA TOSHIBA, Tokyo (JP)

(21) Appl. No.: 13/845,667

(22) Filed: Mar. 18, 2013

(30) Foreign Application Priority Data
Mar. 22, 2012 (JP) 2012-065509

(51) Int. Cl. H01L 27/105

(52) U.S. Cl. CPC H01L 27/1052
USPC 257/319; 438/258

(57) ABSTRACT

A method of manufacturing a nonvolatile semiconductor storage device includes filling an element isolation trench with a sacrificial film; etching a laminate of films to form a plurality of first and second gate electrodes such that the first gate electrodes are disposed in a first region, and the second gate electrodes are disposed in a second region adjacent to the first region; removing the sacrificial film; forming a resist having an opening in the first region; forming a barrier insulating film so as to at least cover an edge of the opening; etching back the barrier insulating film and thereafter removing the resist film; forming an insulating film to form an unfilled gap in the element isolation trench located below the second gate electrode, the second region, and the third region.

### CROSS-REFERENCE TO RELATED APPLICATION(S)

This application is based upon and claims the benefit of priority from Japanese Patent Application No. 2012-065509, filed on, Mar. 22, 2012 the entire contents of which are incorporated herein by reference.

### FIELD

Embodiments disclosed herein generally relate to a nonvolatile semiconductor storage device and a method of manufacturing the same.

### BACKGROUND

In nonvolatile semiconductor device manufacturing, and typically in NAND flash memory manufacturing, downscaling of gate length is being pursued to achieve microfabrication and densification. However, as gate length becomes shorter, the spacing between the adjacent word lines and adjacent bit lines also become smaller which in turn gives rise to a significant degradation in programming speed originating from the parasitic capacitance between the floating gate electrodes of adjacent word lines and adjacent bit lines.

One approach for reducing the parasitic capacitance employs a so called air gap structure as an insulation scheme. For instance, gaps between the adjacent control gate electrodes, between the element regions formed in the substrate, and especially between the adjacent floating gate electrodes formerly filled with an insulating film, a typical example of which is a silicon oxide film, may be filled with air. This reduces the parasitic capacitance between the foregoing elements and consequently increases programming speed because relative dielectric constant εᵣ of air, being approximately 1.0, is much less than approximately 3.9 of silicon oxide film.

However, the implementation of air gap structure involves various technical challenges, one example of which is unintentional filling of the air gap.

### BRIEF DESCRIPTION OF THE DRAWINGS

FIG. 1 partially illustrates one schematic example of an electrical configuration of a NAND flash memory cell region of one embodiment.

FIG. 2 partially illustrates one schematic example of a planar layout of the memory cell region.

FIG. 3A is one schematic example of a vertical cross-sectional view taken along line A-A of FIG. 2.

FIG. 3B is a one schematic example of a vertical cross-sectional view taken along line B-B of FIG. 2.

FIG. 3C is one schematic example of a vertical cross-sectional view taken along line C-C of FIG. 2.

FIG. 3D is one schematic example of a vertical cross-sectional view taken along line D-D of FIG. 2.

FIG. 3E is one schematic example of a vertical cross-sectional view taken along line E-E of FIG. 2.

FIG. 4A is one schematic example of a perspective view illustrating an element isolation trench with a silicon oxide film formed above a patterned resist.

FIG. 4B is one schematic example of a perspective view illustrating an element region with a silicon oxide film formed above a patterned resist.

FIGS. 5A to 17E each illustrate one phase of the manufacturing process flow; where FIGS. 5A, 6A, 7A, 8A, 9A, 10A, 11A, 12A, 13A, 14A, 15A, 16A, and 17A each illustrate one schematic example of a vertical cross-sectional view taken along line A-A of FIG. 2; FIGS. 5B, 6B, 7B, 8B, 9B, 10B, 11B, 12B, 13B, 14B, 15B, 16B, and 17B each illustrate one schematic example of a vertical cross-sectional view taken along line B-B of FIG. 2; FIGS. 5C, 6C, 7C, 8C, 9C, 10C, 11C, 12C, 13C, 14C, 15C, 16C, and 17C each illustrate one schematic example of a vertical cross-sectional view taken along line C-C of FIG. 2; FIGS. 5D, 6D, 7D, 8D, 9D, 10D, 11D, 12D, 13D, 14D, 15D, 16D, and 17D each illustrate one schematic example of a vertical cross-sectional view taken along line D-D of FIG. 2; and FIGS. 5E, 6E, 7E, 8E, 9E, 10E, 11E, 12E, 13E, 14E, 15E, 16E, and 17E each illustrate one schematic example of a vertical cross-sectional view taken along line E-E of FIG. 2.

### DESCRIPTION

In one embodiment, a method of manufacturing a nonvolatile semiconductor storage device is disclosed. The method includes forming a gate insulating film and a first electrode film in the listed sequence above a semiconductor substrate; forming an element isolation trench along a first direction into the first electrode film, the gate insulating film, and the semiconductor substrate to define an element region isolated in a second direction; filling the element isolation trench with a sacrificial film; forming an interelectrode insulating film, and a second electrode film in the listed sequence above the element region and the sacrificial film; etching the second electrode film, the interelectrode insulating film, and the first electrode film along a second direction to form a plurality of first gate electrodes and a plurality of second gate electrodes such that the first gate electrodes are disposed in a first region, and the second gate electrodes are disposed in a second region adjacent to the first region, selectively removing the sacrificial film in the element isolation trench after the formation of the first and the second gate electrodes; and forming a resist, after the removal of the sacrificial film, and patterning the resist to define an opening in the first region; forming a barrier insulating film, after patterning the resist, so as to at least cover an edge of the opening; etching back the barrier insulating film to expose the resist film such that the barrier insulating film remains at least partially in the first region and thereafter removing the resist film; forming a first insulating film, after removal of the resist film, across the first region, the second region, and the third region to form an unfilled gap in the element isolation trench located below the second region, the second region; and forming a second insulating film above the first insulating film.

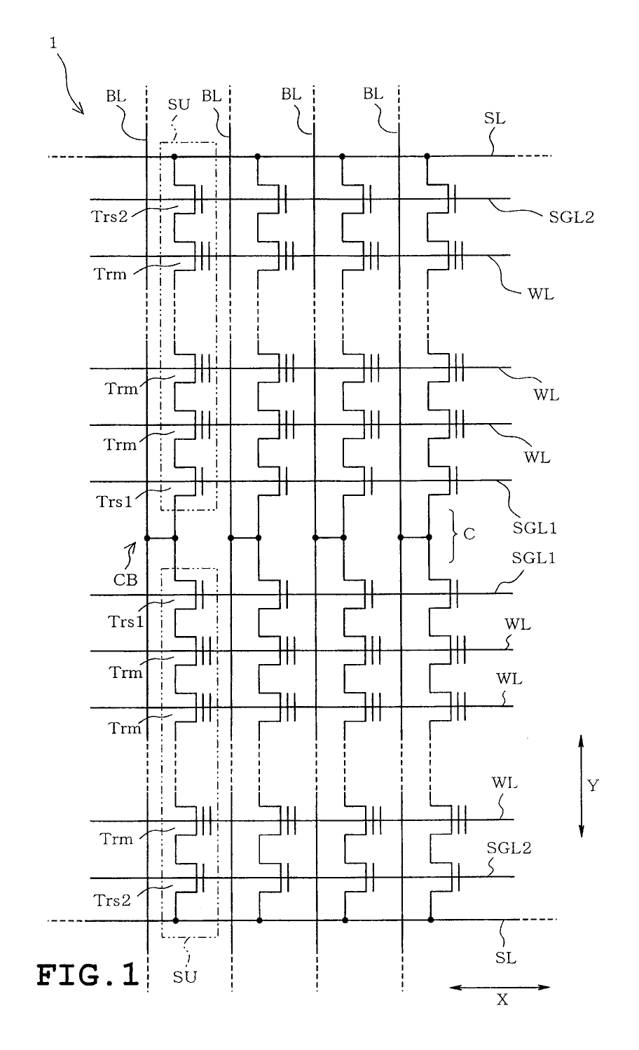

Embodiments are described hereinafter through a NAND flash memory application with references to FIGS. 1 to 17E. The drawings are not drawn to scale and thus, do not reflect the actual measurements of the features such as the correlation of thickness to planar dimensions and the relative thickness of different layers. Further, directional terms such as up, upper, upward, down, lower, downward, left, leftward, right, and rightward are used in a relative context with an assumption that the worked surface of the later described semiconductor substrate faces up. Thus, the directional terms do not necessarily correspond to the directions based on gravitational acceleration.

The description begins with a brief overview of the structure of one embodiment of a NAND flash memory.

FIG. 1 is one example of a partial equivalent circuit representation of a memory cell array located in a memory cell region of NAND flash memory 1.

Referring to FIG. 1, the memory cell array includes multiplicity of units of cells also referred to as NAND cell unit SU or a NAND string arranged in rows and columns. NAND cell unit SU comprises a multiplicity of series connected memory cell transistors Trm, such as 64 in number, situated between a couple of select transistors Trs1 and Trs2 that are located at Y-direction ends of NAND cell unit SU. The neighboring memory cell transistors Trm within NAND cell unit SU share their source/drain regions.

The X-direction aligned memory cell transistors Trm shown in FIG. 1 are interconnected by common word line WL extending in the X direction, whereas the X-direction aligned select transistors Trs1 are interconnected by common select gate line SGL1 extending in the X direction and likewise, the X-direction aligned select transistors Trs2 are interconnected by common select gate line SGL2 also extending in the X direction. The drain of each select transistor Trs1 is coupled to bit line BL by way of bit line contact CB shown in FIG. 1. Bit line BL extends in the Y direction orthogonal to the X direction shown in FIG. 1. The source of each select transistor Trs2 is coupled to source line SL extending in the X-direction.

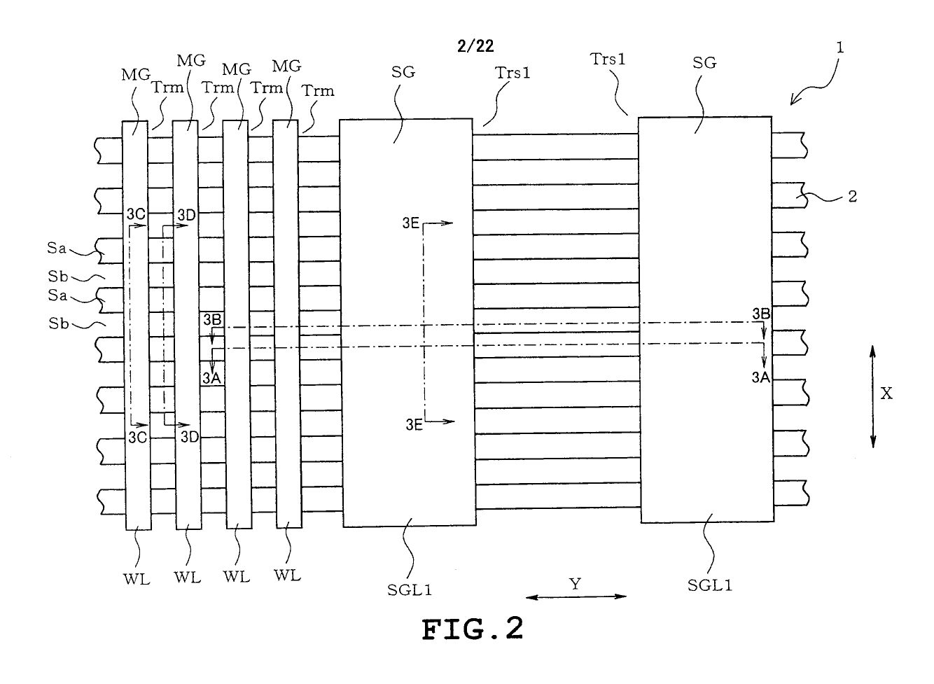

FIG. 2 partially illustrates one example of a planar layout of the memory cell region. FIG. 2 does not show bit line contact CB for simplicity. As shown in FIG. 2, multiplicity of element isolation regions Sb run in the Y direction as viewed in FIG. 2 of a p-type silicon substrate 2, or more generally, semiconductor substrate 2. Element isolation regions Sb are separated from one another in the X direction as viewed in FIG. 2 to isolate element regions Sa, running in the Y-direction, by a predetermined space interval in the X direction. The isolation employs a shallow trench isolation scheme known as STI. The trenches represented as element isolation trenches 2d are left unfilled instead of being filled with an insulating film to define a so called air gap or unfilled gap.

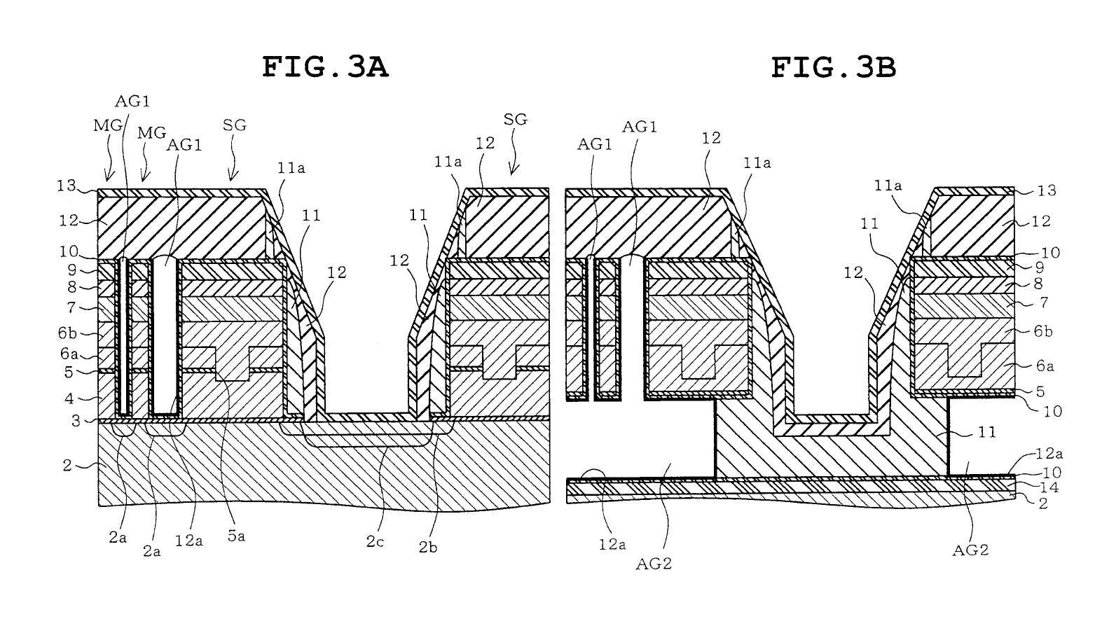

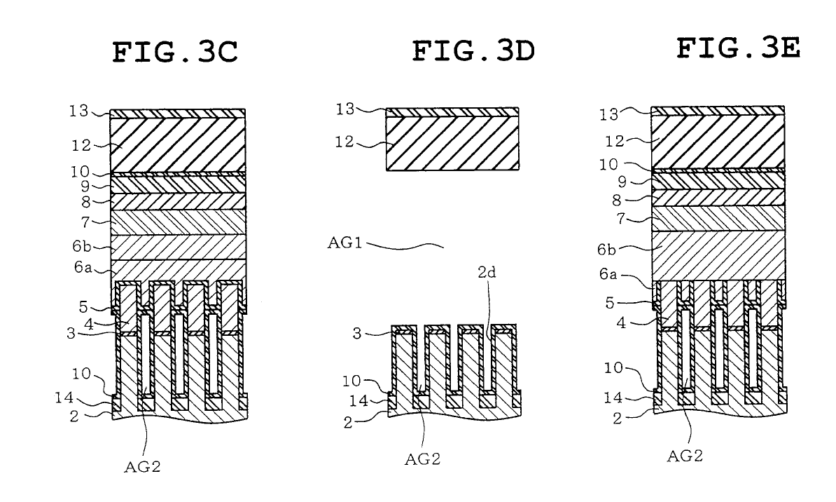

Multiplicity of word lines WL, spaced from one another in the Y direction by a predetermined spacing, extend in the X direction as viewed in FIG. 2 which is the direction orthogonal to the Y direction in which element region Sa extends. Above element region Sa intersecting with word line WL, gate electrode MG of memory cell transistor Trm shown in FIG. 3A is formed. Gate electrode MG is also referred to as a second gate electrode.

As described earlier, Y-directionally adjacent memory cell transistors Trm are situated between a couple of select transistors Trs1 and Trs2 that are located at Y-direction ends of NAND cell unit SU. Multiplicity of select transistors Trs1 are aligned in the X direction and are electrically interconnected by a common select gate line SGL1 as described earlier. Select gate electrode SG also referred to as a first gate electrode is formed above element region Sa intersecting with select gate line SGL1. Similarly, though not shown in FIG. 2, multiplicity of select transistors Trs2 are aligned in the X direction and are electrically interconnected by a common select gate line SGL2 as described earlier. Select gate electrode SG also referred to as a first gate electrode is formed above element region Sa intersecting with select gate line SGL2.

FIG. 3A is a cross sectional view taken along line A-A of FIG. 2 and illustrates one example of a cross sectional structure of the element region including a couple of select transistors Trs1 and memory cell transistors Trm located adjacent to select transistor Trs1.

FIG. 3B is a cross sectional view taken along line B-B of FIG. 2 and illustrates one example a cross sectional structure of the element isolation region having a couple of select transistors Trs1 and memory cell transistors Trm located adjacent to select transistor Trs1 formed above it.

FIG. 3C is a cross-sectional view taken along line C-C of FIG. 2 and illustrates one example of a cross sectional structure of memory cell transistor Trm taken along word line WL.

FIG. 3D is a cross-sectional view taken along line D-D of FIG. 2 and illustrates one example of a cross sectional structure of memory cell transistor Trm taken along the region between word line WL.

FIG. 3E is a cross-sectional view taken along line E-E of FIG. 2 and illustrates one example of a cross sectional structure of select transistor Trs1 taken along select gate line SGL1.

In the following description, select transistors Trs1 and Trs2 may be collectively referred to as select transistor Trs.

As shown in FIG. 3A, gate insulating film 3 is formed above silicon substrate 2 and more specifically in the element region of silicon substrate 2 in which memory cell transistors Trm and select transistors Trs are formed. Gate insulating film 3 is also referred to as a tunnel oxide film and may comprise a silicon oxide film. Memory cell transistor Trm comprises gate electrode MG formed above gate insulating film 3 and source/drain region 2a. As described earlier, multiple memory cell transistors Trm are aligned in the Y direction to form NAND cell unit SU which terminate with a pair of select transistors Trs provided on both Y directional ends.

Gate electrode MG of memory cell transistor Trm includes a floating gate electrode, interelectrode insulating film 5, a control gate electrode and silicide film 7. The floating gate electrode comprises polysilicon film 4 also referred to as a first electrode film. The control gate electrode comprises polysilicon films 6a and 6b also referred to as a second electrode film. Interelectrode insulating film 5 may take an ONO structure comprising a stack of oxide/nitride/oxide films, which may be provided with additional bottom and top nitrides to take a NONON structure or may also comprise an insulating film possessing high dielectric constant. Polysilicon films 6a and 6b are formed separately as will be later described in detail but collectively serve as the second electrode film. Silicon nitride film 8 and silicon oxide film 9 are further formed above silicide film 7.

In the surface layer of silicon substrate 2 located between gate electrodes MG and between gate electrodes SG and MG, source/drain region 2a doped with impurities is formed. In the surface layer of silicon substrate 2 located between gate electrodes SG, LDD (lightly doped drain) region 2b is formed which serves as a drain region. Source/drain region 2a and LDD region 2b are formed by doping impurities into the surface layer of silicon substrate 2. Further in the surface layer of silicon substrate 2 located between gate electrodes SG, drain region 2c heavily doped with impurities is formed to obtain an LDD structure.

Select gate electrode SG of select transistor Trs is substantially identical in structure to gate electrode MG of memory cell transistor Trm and thus, is configured by polysilicon film 4, interelectrode insulating film 5, polysilicon films 6a and 6b, and silicide film 7 stacked in the listed sequence above gate insulating film 3. Select gate electrode SG differs from memory cell gate electrode MG in that through hole 5a penetrates the central portion of interelectrode insulating film 5 to establish physical contact and electric conduction between polysilicon film 4, and polysilicon films 6a, and 6b. Gate electrodes SG of select transistors Trs1 and Trs2 are identical in structure and thus, are not differentiated in the drawings.

In one embodiment, silicide film 7 located on the upper portion of gate electrode MG and select gate electrode SG comprises a tungsten silicide film. Silicide film 7 may alternatively be formed by forming a metal film above polysilicon film 6b and siliciding polysilicon film 6b by thermal treatment.

The upper surfaces and sidewalls of gate electrode MG and select gate electrode SG, the surface of gate insulating film 3 situated between gate electrodes MG and between select gate electrodes MG and SG are lined with a thin silicon oxide film 10. Along the opposing sidewalls of the couple of opposing gate electrodes SG, spacer 11 comprising a silicon oxide film is formed which serves as a barrier insulating film. Spacer 11a comprising a silicon oxide film is also formed above the upper surface of gate electrode SG.

As shown in FIG. 3A, the gaps between gate electrodes MG and between gate electrode MG and SG are not filled with any gap fill material and are enclosed by silicon oxide film 12 also referred to as a first insulating film running across the upper portions of the foregoing gaps to define air gap AG1. Silicon oxide film 12 is formed under conditions providing poor step coverage and thus, allows formation of air gap AG1 without filling the gaps. It is to be appreciated that a thin silicon oxide film 12a is formed along the sidewalls of gate electrodes MG and gate electrodes SG during the initial stage of the formation of silicon oxide film 12. Silicon oxide film 12 is etched back after its formation to the extent to remain along the sidewall of spacer 11. Silicon oxide film 13 also referred to as second insulating film is further blanketed over the foregoing features.

Referring to FIG. 3B, the cross section taken along the element isolation trench 2d, corresponding to the cross section taken along line B-B of FIG. 2, shows that silicon oxide film 14 is formed above the bottom surface of element isolation trench 2d formed into silicon substrate 2. As will be later described in the manufacturing process flow, silicon oxide film 14 is a remnant of a sacrificial film which was temporarily filled in element isolation trench 2d and later selectively removed. Silicon oxide film 14 comprises a coating type oxide film formed based on a polysilazane coating liquid. In an alternative embodiment, silicon oxide film 14 may be completely removed. The aforementioned silicon oxide film 10 is formed above the remnant silicon oxide film 14. As shown in FIG. 3B, element isolation trench 2d located below gate electrodes MG is configured as air gap AG2 which provides insulation without being filled with any gap fill materials. The portion of element isolation trench 2d located below select gate electrode SG is partially configured as air gap AG2. Gate electrodes MG and SG extend in the X direction over element isolation trench 2d from one element region to another as can be seen also in FIG. 2. Further, air gap AG1 is formed between gate electrodes MG and between gate electrodes MG and SG.

The portion of element isolation trench 2d located between gate electrodes SG, is filled with the barrier insulating film which also serves as spacer 11 as mentioned earlier, and thus, this portion does not constitute air gap AG2. As mentioned earlier, a thin silicon oxide film 12a is formed during the formation of silicon oxide film for enclosing air gaps AG1 and AG2. FIG. 3B shows the thin silicon oxide film 12a lined along silicon oxide film 10 and silicon oxide film 11.

In the regions where memory cell transistor Trm is formed, air gap AG1 is formed between gate electrodes MG and air gap AG2 is formed in element isolation trenches 2d. Because air gaps AG1 and AG2 are not filled with insulators such as a silicon oxide film having a relative dielectric constant εᵣ of approximately 3.9, but is empty or filled with air having a relatively low dielectric constant εᵣ of approximately 1.0. Thus, the level of parasitic capacitance can be relatively reduced to thereby accelerate programming speed.

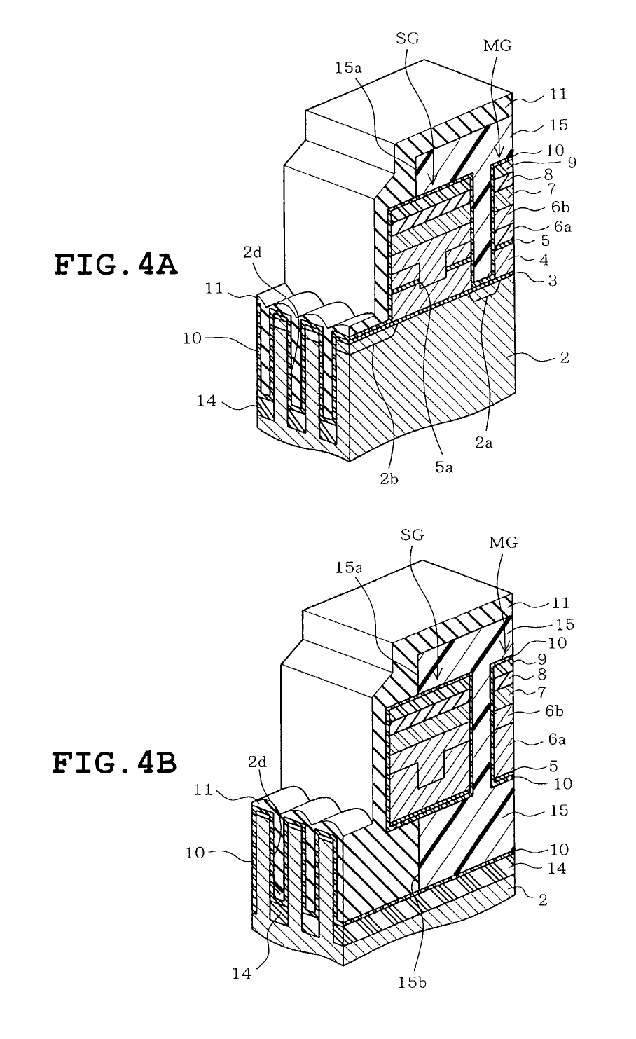

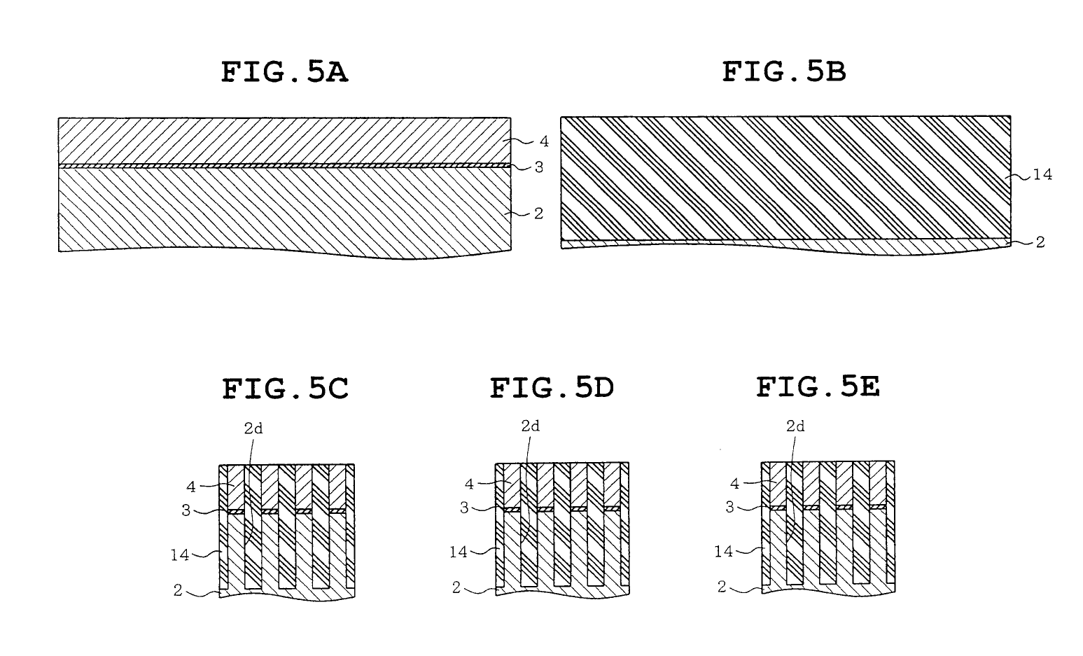

Next, a description will be given on one example of a manufacturing process flow of the above described structure with reference to FIGS. 4A, 4B, and FIGS. 5A to 17E. FIGS. 4A and 4B are examples of 3 dimensional views of one phase of the manufacturing process flow described hereinafter. The description of the manufacturing process flow will be given with sequential reference to the drawings beginning with FIG. 5A. The following descriptions will focus on the features of the embodiments and thus, known steps may be added or removed from the process flow as required. Further, the sequence of the process flow may be rearranged if practicable.

Referring to FIGS. 5A to 5E, description will be given on the formation of element isolation trench 2d and filling of element isolation trench 2d with silicon oxide film 14.

Referring to FIG. 5A, gate insulating film 3 comprising a silicon oxide film is formed above a p-conductive type silicon substrate 2. In one embodiment, gate insulating film 3 may be formed by thermal oxidation. Polysilicon film 4 later formed into floating gate electrode is deposited above gate insulating film 3 by LPCVD (Low Pressure Chemical Vapor Deposition). Polysilicon film 4 may be doped with n-type impurities such as phosphorous (P) or p-type impurities such as boron (B). Silicon nitride film serving as a working film not shown is formed above polysilicon film 4.

Using photolithography, the silicon nitride film, polysilicon film 4, gate insulating film 3, and the upper portion of silicon substrate 2 is etched to form element isolation trench 2d which runs in the Y direction along the cross section of FIGS. 5A and 5B. Multiplicity of element isolation trenches 2d are aligned in the X direction along the cross section of FIGS. 5C to 5E which is orthogonal to the Y direction. Element isolation trench 2d delineates the surface of silicon substrate 2 into element regions Sa and element isolation region Sb. Element isolation trenches 2d are overfilled with a polysilazane coating liquid so that the entire structure is coated with the polysilazane coating liquid. The polysilazane coating liquid is subjected to a weak level of thermal treatment to transform the polysilazane coating liquid into silicon oxide film 14. The thermal treatment is controlled to a weak level so that the resulting silicon oxide film 14 serves as a sacrificial film which can be selectively removed with ease later in the manufacturing process flow.

The excess silicon oxide film 14 overflowing from element isolation trench 2d is removed by CMP (Chemical Mechanical Polishing) using the silicon nitride film as a stopper so that silicon oxide film 14 remains filled in element isolation trench 2d. The silicon nitride film is removed by a wet process and silicon oxide film 14 is etched back to be substantially level with polysilicon film 4.

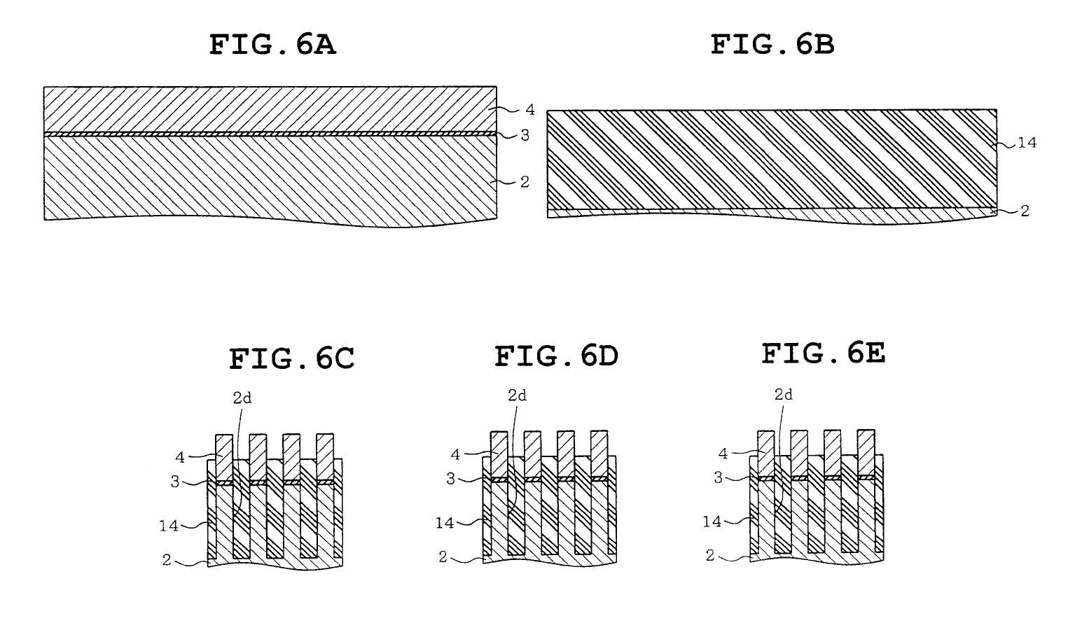

Referring to FIGS. 6A to 6E, silicon oxide film 14 is etched back to a predetermined depth from its original height by RIE (Reactive Ion Etching) so that polysilicon film 4 projects relatively higher than silicon oxide film 14.

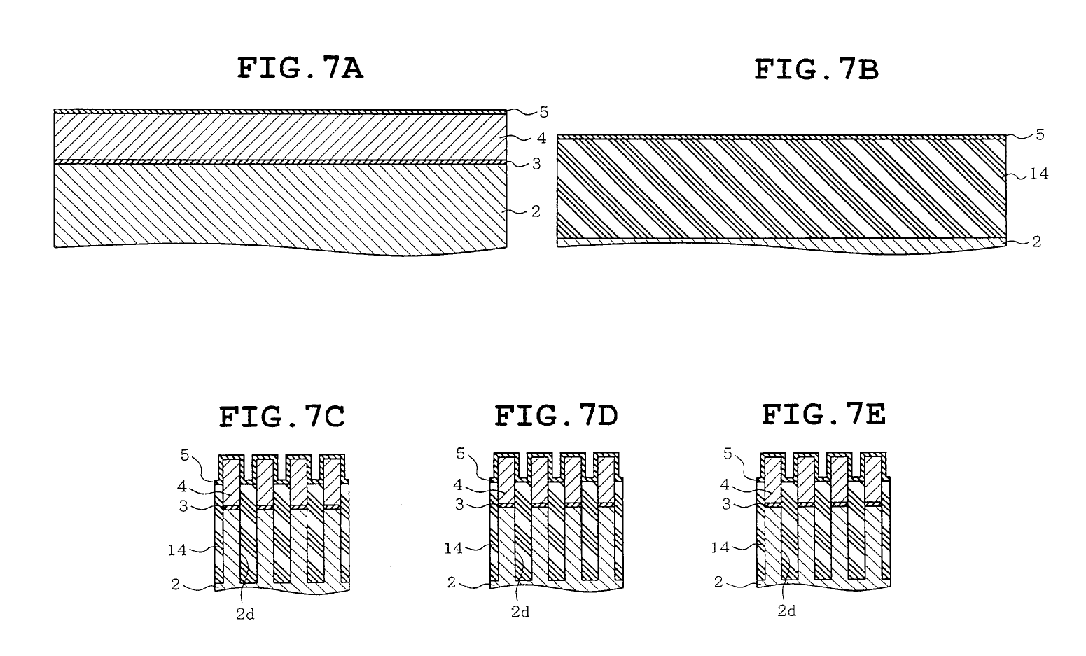

Referring to FIGS. 7A to 7E, interelectrode insulating film 5 is formed above the upper surface of polysilicon film 4 and the upper surface of silicon oxide film 14 by deposition of films such as an ONO (Oxide-Nitride-Oxide) film by LPCVD. NONON film may be employed instead of the ONO film which may be obtained, for example, by radically nitriding the lowermost oxide film and the uppermost oxide film of the ONO film. Still alternatively, the middle nitride film of the ONO film may be replaced by a high dielectric constant film such aluminum oxide also referred to as alumina or hafnium oxide.

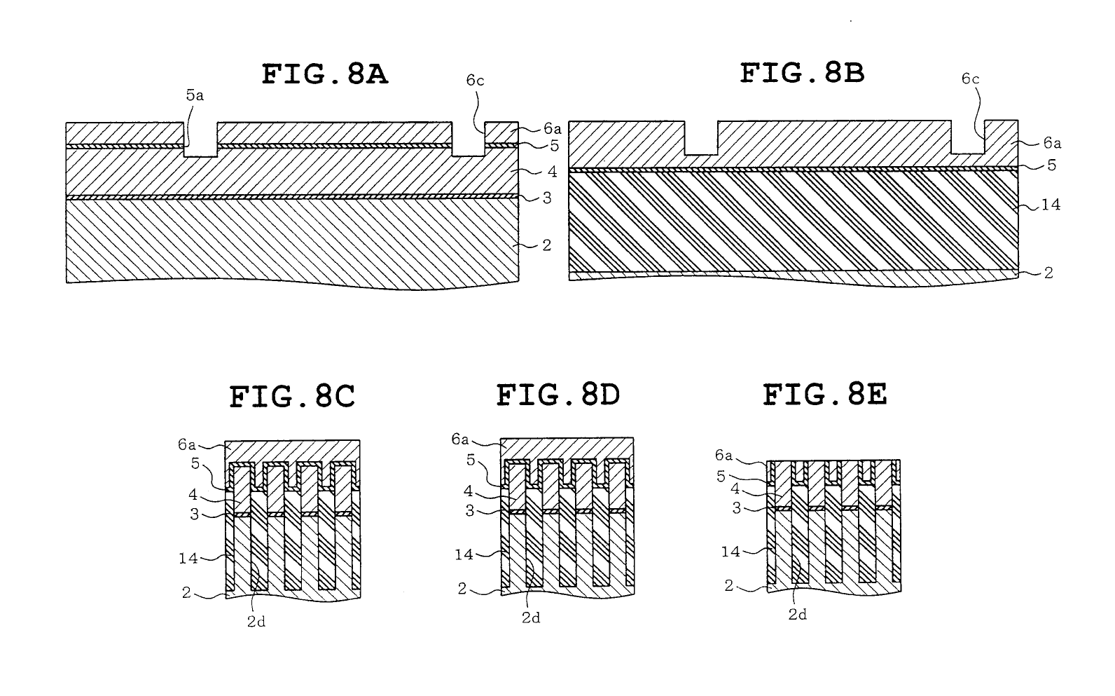

Referring to FIGS. 8A to 8E, first polysilicon film 6a is formed by CVD. First polysilicon film 6a is later formed into a control gate electrode. Using photolithography, opening is etched into the upper surface of first polysilicon film 6a which extends through first polysilicon film 6a, interelectrode insulating film 5, and partially through polysilicon film 4. The opening is formed in the gate electrodes of transistors that are not provided with a floating gate electrode such as the select gate electrode of the select gate transistor and the gate electrode of the peripheral circuit transistor. The opening renders polysilicon film 4 to be electrically conductive with first polysilicon film 6a and second polysilicon film 6b as will be later described.

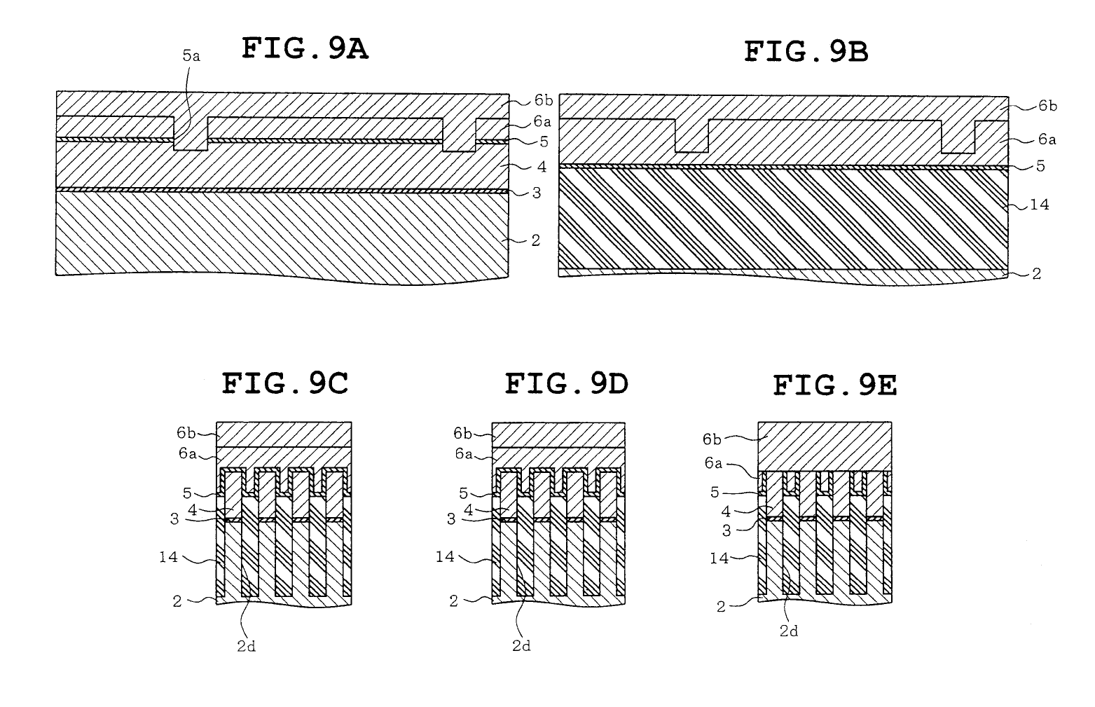

Referring to FIGS. 9A to 9E, the recess represented as opening 5a extending through interelectrode insulating film 5 is overfilled with second polysilicon film 6b. As a result, polysilicon films 4, 6a, and 6b are rendered electrically conductive by way of opening 5a extending through interelectrode insulating film 5.

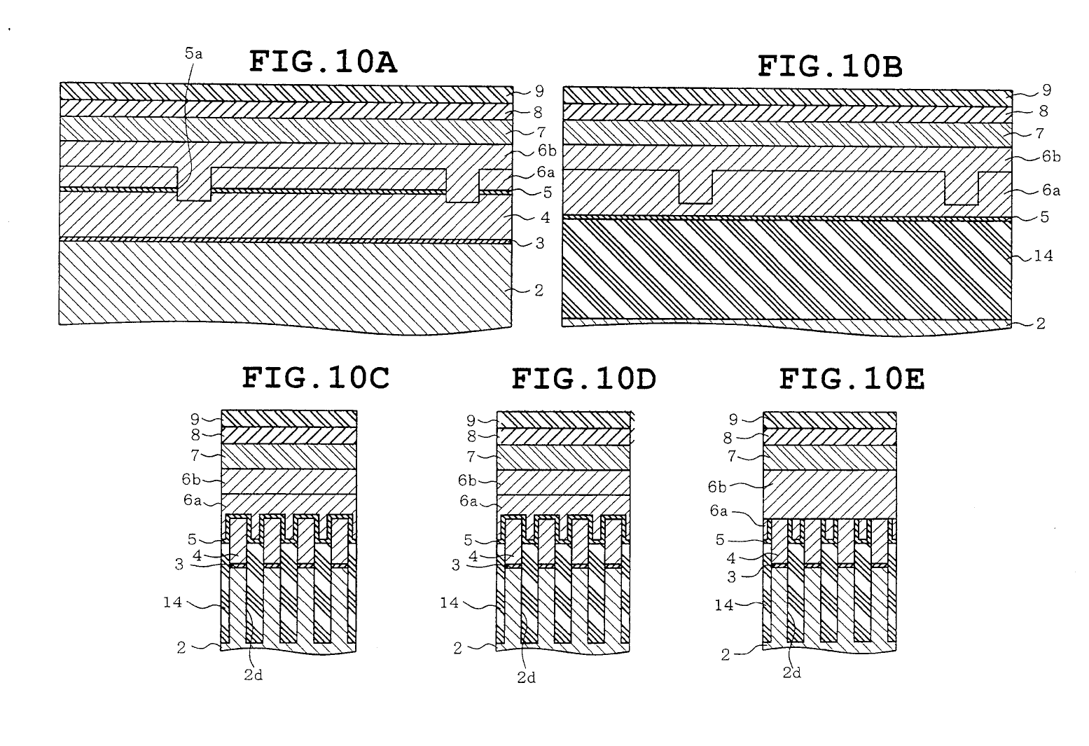

Referring to FIGS. 10A to 10E, silicide film 7 comprising a tungsten silicide, silicon nitride film 8, and silicon oxide film 9 are formed in the listed sequence above second polysilicon film 6b. Silicon nitride films 8 and 9 are insulating films also serving as a working film used in forming the gate structure.

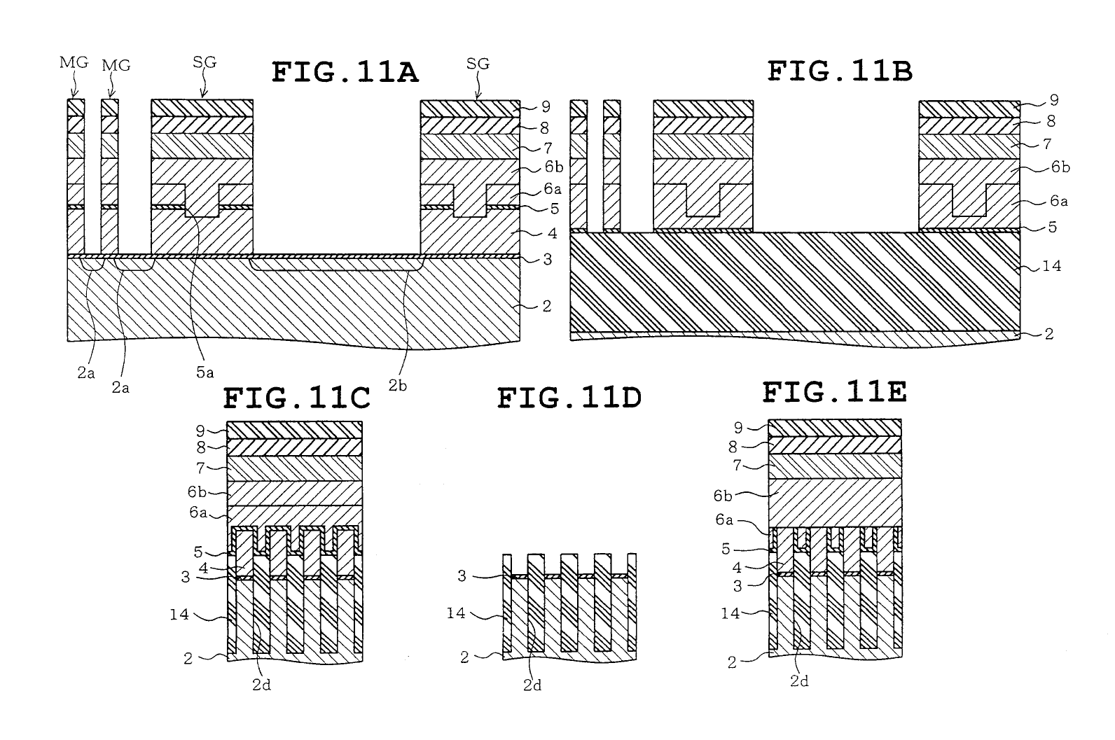

Referring to FIGS. 11A to 11E, a resist film is formed and patterned into line and space pattern in the memory cell region, whereas in the peripheral circuit region, the resist film is patterned into a predetermined circuit layout. Using the patterned resist as a mask, silicon oxide film 9 is patterned to form a hard mask which is used to etch silicon nitride film 8 by anistropic etching such as RIE.

Polycrytalline silicon films 6b and 6a, interelectrode insulating film 5, and polysilicon film 4 are further anisotropically etched by RIE to isolate gate electrodes MG and gate electrodes SG. The aforementioned opening 5a formed through interelectrode insulating film 5 is maintained in gate electrodes SG. The anisotropic etching may progress to the extent to thin gate insulating film 3 or even progress into silicon substrate 2 to remove gate insulating film 3. Using gate electrodes MG and SG and silicon nitride film 15 as masks, n-type impurities such as phosphorous is introduced into the surface of silicon substrate 2 by an ordinary ion implantation. The implanted impurities are thermally treated to obtain source/drain region 2a and LDD region 2d. The source region is formed in a similar manner.

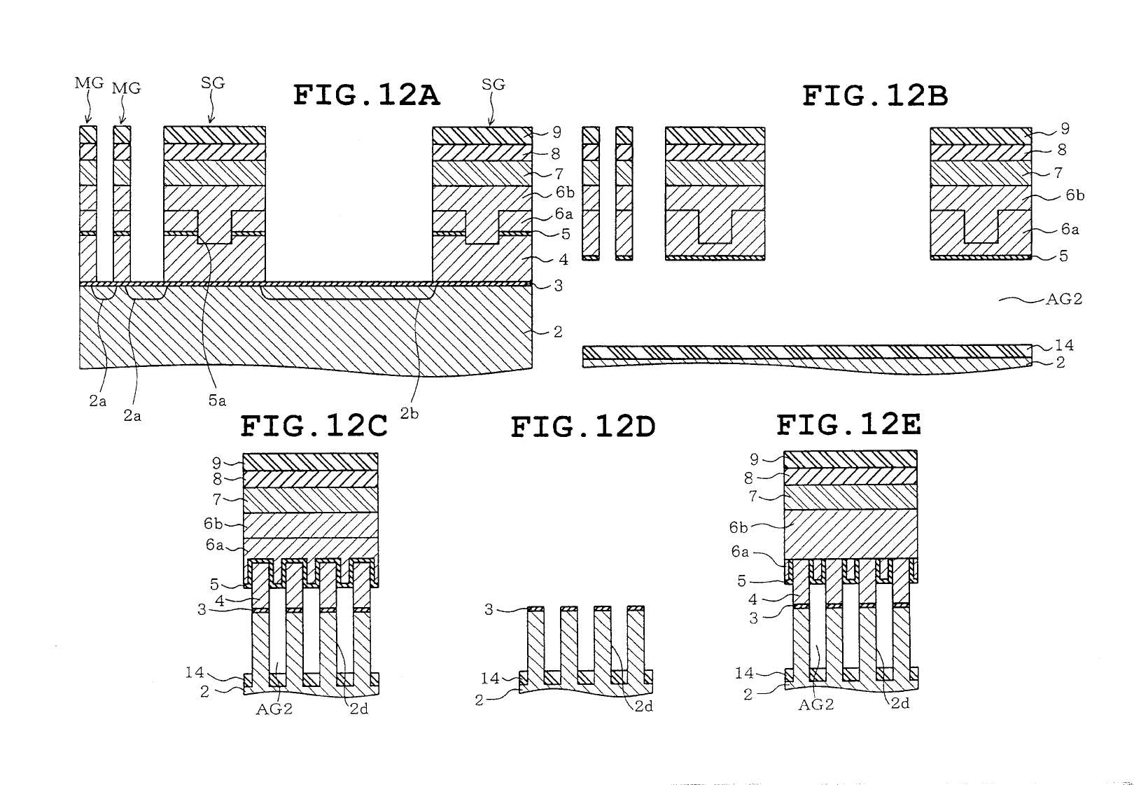

Referring to FIGS. 12A to 12E, silicon oxide film 14 serving as a sacrificial film is selectively etched by a fluorine-based chemical liquid. Silicon oxide film 14 in element isolation trench 2d is thus, etched to a predetermined depth such that most of silicon oxide film 14 below gate electrode MG and SG are removed to define air gap AG2 in this area.

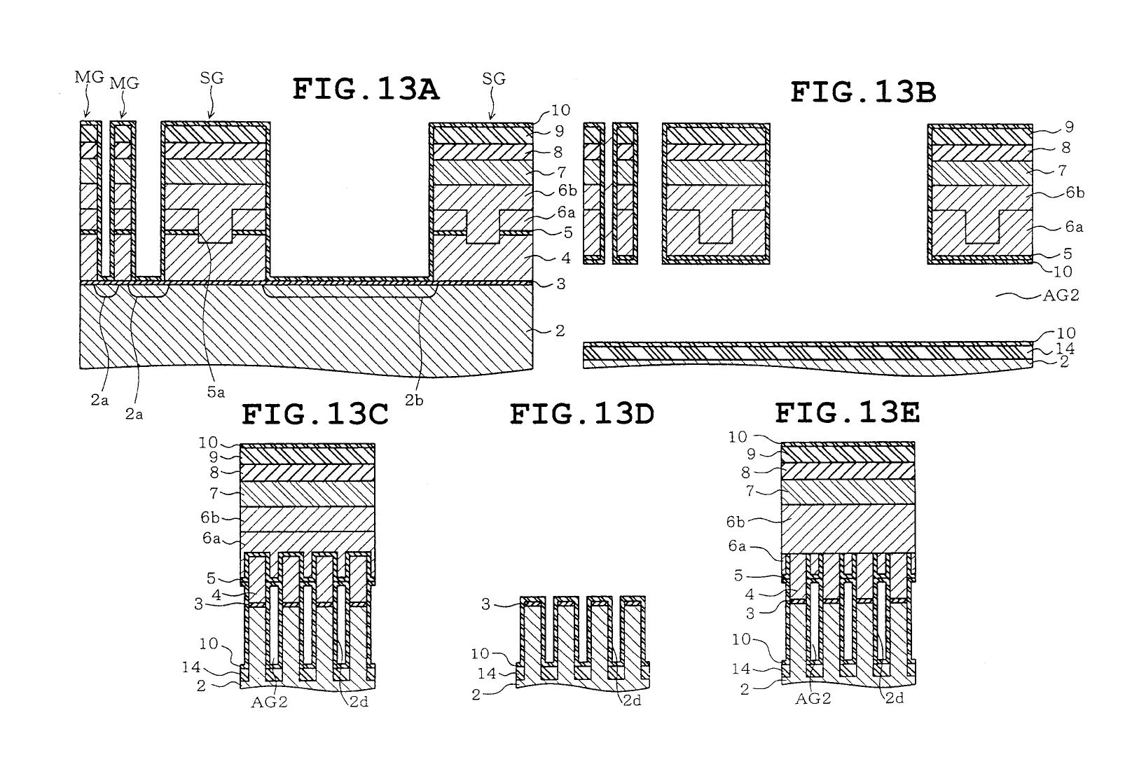

Referring to FIGS. 13A to 13E, silicon oxide film 10 serving as a thin spacer is blanketed over the entire structure by CVD. As shown in FIGS. 13A to 13E, silicon oxide film 10 is lined along the upper surface, sidewall, and the exposed underside of gate electrodes MG and SG as well as along the surface of silicon substrate 2 and the upper surface of silicon oxide film 14.

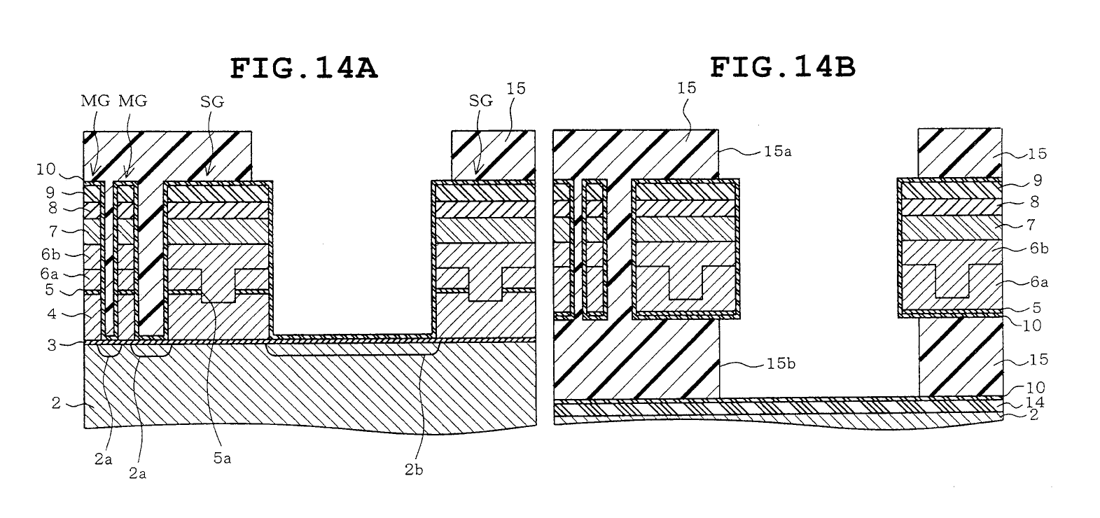

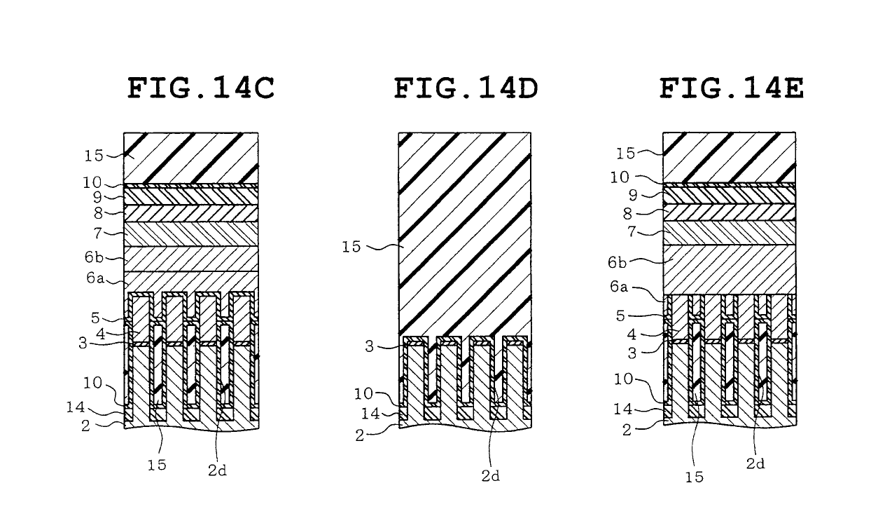

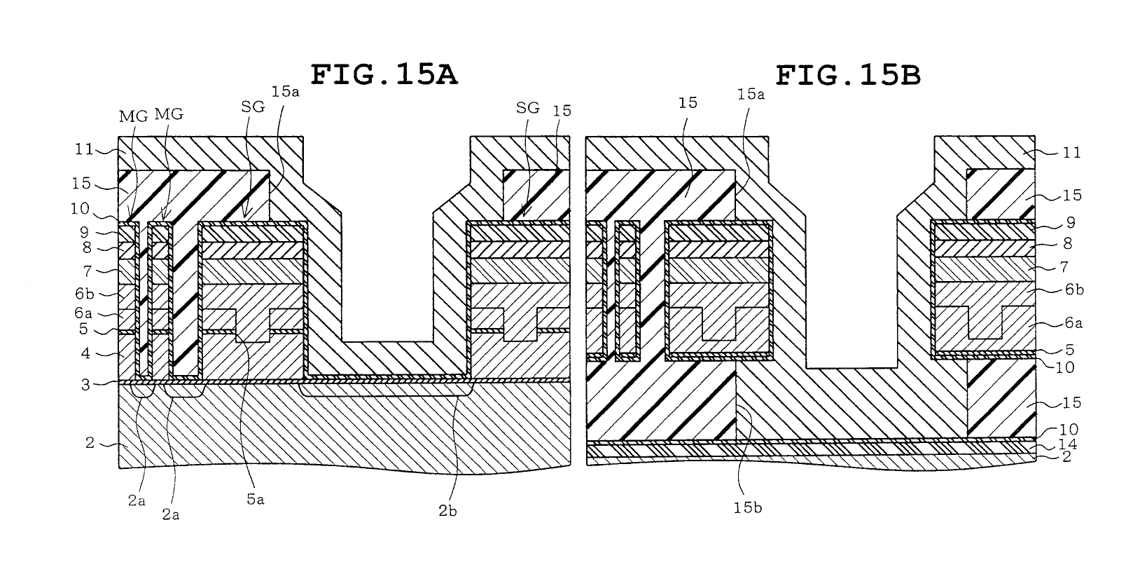

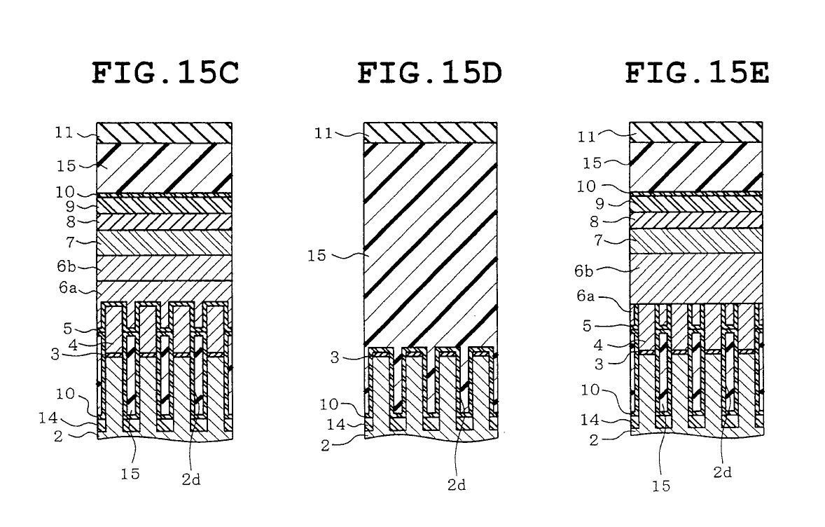

Referring to FIGS. 14A to 14E, negative-type resist 15 is coated and patterned to define openings 15a and 15b as shown. Openings 15a and 15b are located in the portion where gate electrodes SG of select transistors Trs face one another. Opening 15a is defined by an edge located above the upper surface of gate electrode SG and displaced toward gate electrode MG by a predetermined distance from the sidewall of gate electrode SG facing the opposing select gate electrode SG. Opening 15b is defined by an edge located below gate electrode SG and inside element isolation trench 2d. Because resist 15 is a negative type, the portion exposed to light remains, whereas the portion unexposed to light is dissolved when developed to define an opening. In the example shown in FIG. 15B, the mask overlying resist is patterned to cover the portion between gate electrodes SG while leaving the rest of the portions uncovered. Thus, resist 15 located in the uncovered portions are exposed to light and thus, remains after development. Resist 15 located in element isolation trench 2d below gate electrodes MG and SG is exposed to diffracted light and thus, remains after development.

Referring to FIGS. 15A to 15E, silicon oxide film 11 is formed over the patterned resist 15. In one embodiment, silicon oxide film 11 comprises a low temperature silicon oxide film which can be formed in low temperatures without affecting resist film 15. Thus, as typically shown in FIG. 15B, silicon oxide film 11 is formed along resist 15 and consequently fills openings 15a and 15b.

FIGS. 4A and 4B are examples of three-dimensional views corresponding to FIGS. 15A and 15B and schematically shows how silicon oxide film 11 and resist 15 are formed. In the region between gate electrodes SG, silicon oxide film 11 is formed so as to cover the portions of silicon substrate 2 where resist film 15 is not formed and further fill element isolation trench 2d.

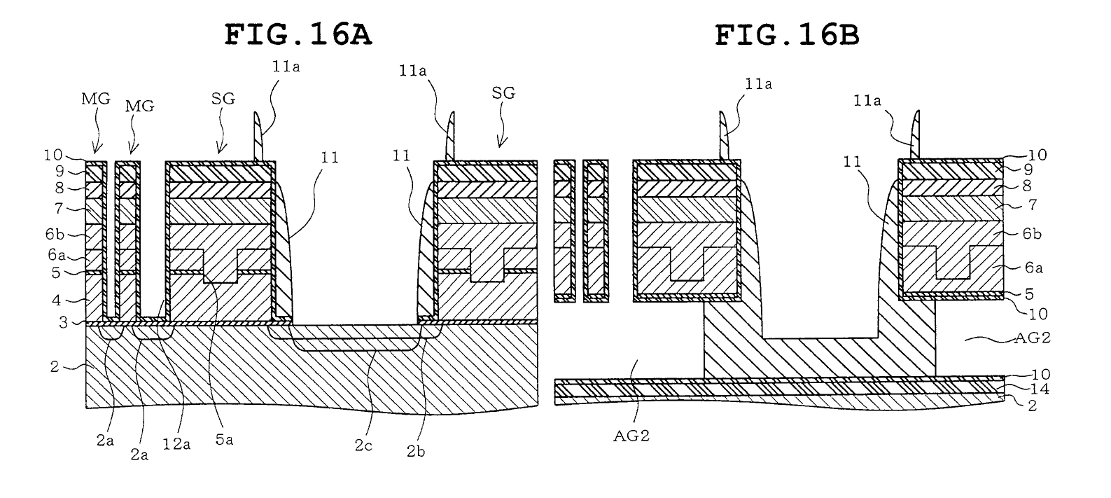

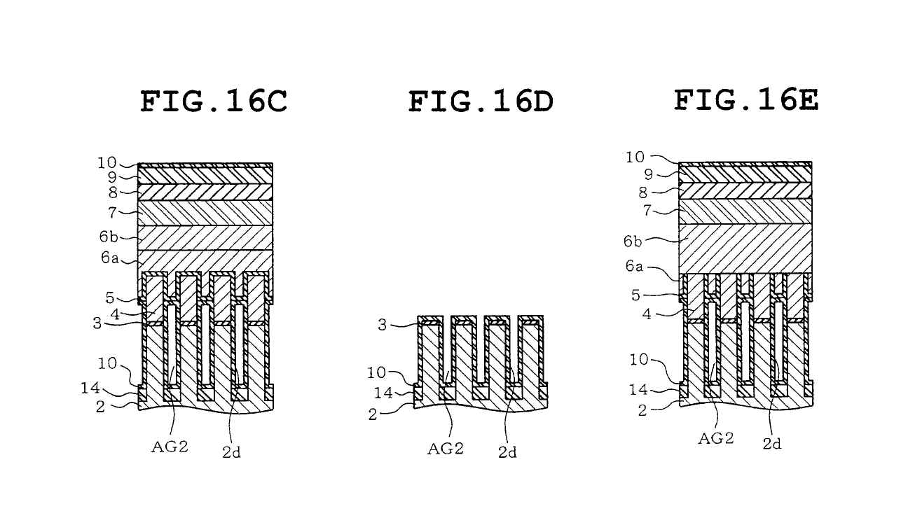

Referring to FIGS. 16A to 16E, silicon oxide film 11 is etched back by RIE and formed into spacer 11. More specifically, silicon oxide film 11 located along the sidewall of gate electrode SG remains as spacer 11, while silicon oxide film 11 formed along opening 15a of resist film 15 located above gate electrode SG remains as spacer 11a. Silicon oxide film 11 in element isolation trench 2d located between gate electrodes SG is only partially etched back and keeps the upper surface of silicon oxide film 10 covered. Resist film 15 exposed as the result of etch back of silicon oxide film 11 is removed by ashing, etc.

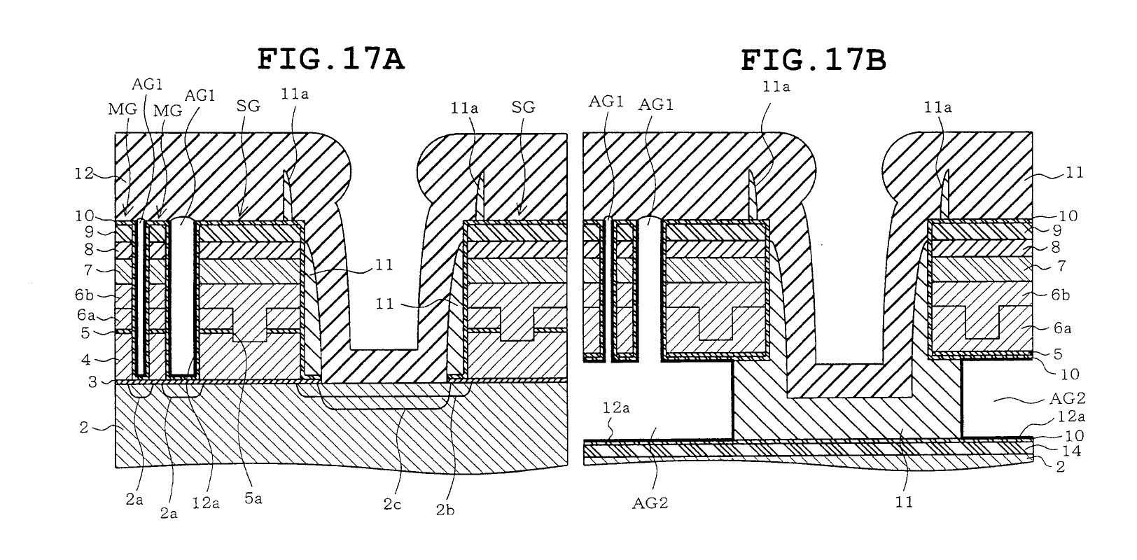

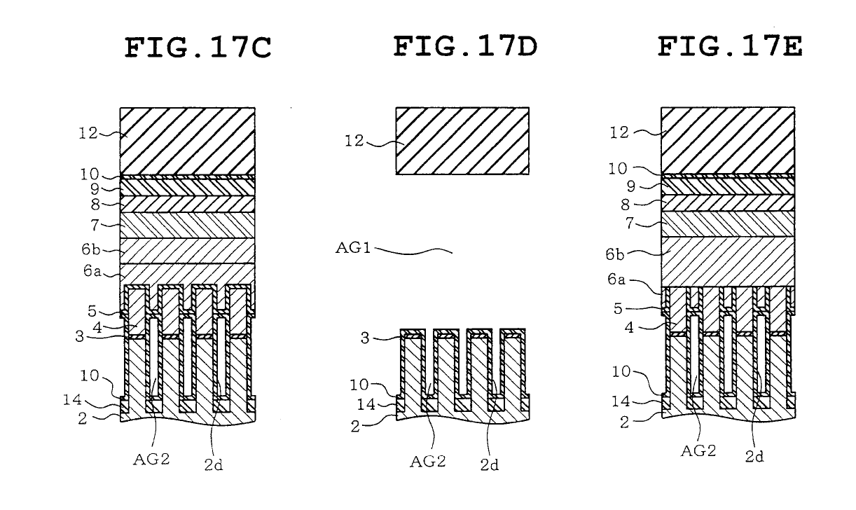

Referring to FIGS. 17A to 17E, silicon oxide film 12 is blanketed above the entire structure by CVD with a recipe providing poor step coverage. As a result, a thin silicon oxide film 12a is lined along the opposing sidewalls of adjacent gate electrodes MG and along the opposing sidewalls of adjacent gate electrodes MG and SG, whereafter relatively thicker silicon oxide film 12 is formed so as to enclose the upper portion of the gaps between the foregoing electrodes to define air gap AG1. The gap located inside element isolation trench 2d is also enclosed by silicon oxide film 12 formed across the electrode gaps and is further enclosed by silicon oxide film 11 filled between gate electrodes SG, to thereby define air gap AG2.

As typically shown in FIG. 17B, silicon oxide film 12 is formed so as to cover silicon oxide film 11 overlying the bottom of element isolation trench 2d located in the portion between gate electrodes SG. Further, as typically shown in FIG. 17B, silicon oxide film 12 hangs over the gap between gate electrodes SG so as narrow the upper opening of the gap.

Referring back to FIGS. 3A to 3E, silicon oxide film 12 located between select gate electrodes SG is etched back by photolithography. More specifically, a resist is formed and patterned to have an opening in the portion above the gap between select gate electrodes SG. Using the resist as a mask, silicon oxide film 12 exposed by the opening is thinned by RIE to be formed into a spacer-like shape and the resist is removed by ashing. As a result, the upper portion of silicon oxide film 12 located between select gate electrodes SG is formed into a wide spreading opening.

Silicon oxide film 13 is further blanketed above the entire structure to serve as a liner film. The foregoing manufacturing process flow results in the structure shown in FIGS. 3A to 3E. Another liner film comprising a silicon nitride film is further blanketed above silicon oxide film 13 which is further topped by an interlayer insulating film. The silicon nitride film also serves as a barrier film to inhibit intrusion of water and other foreign objects. Contact is formed through the interlayer insulating film and the manufacturing process flow continues though not discussed herein.

In the embodiments discussed above, element isolation trench 2d located between select gate electrodes SG is filled with silicon oxide film 11 after silicon oxide film 14 serving as a sacrificial film is removed. Thus, in the subsequent formation of silicon oxide film 12 serving as a liner film, silicon oxide film 11 serves as a barrier to prevent silicon oxide film 12 from being formed in the gate electrode MG side of element isolation trench 2d through the gap between select gate electrodes SG. Air gap AG1 is thus, formed between gate electrodes MG and between gate electrodes MG and SG and air gap AG2 is formed in element isolation trench 2d.

The provision of air gaps AG1 and AG2 in the memory cell array reduces the parasitic capacitance exerted in the direction of word line WL and in the direction of bit line BL which in turn narrows the threshold voltage distribution of the memory cell transistors while reducing the fringe capacitance between the control gate electrode and silicon substrate 2. Thus, improvement in coupling ratio is achieved which allows reduction in programming voltage Vpgm.

Further, the provision of an air gap between gate electrode SG of select transistor Trs and gate electrode MG of memory cell transistor Trm adjacent to select transistor Trs in the bit line direction and the provision of air gaps between the floating gate electrodes suppresses the influence of the fringe field from the control gate electrode. This improves channel controllability and channel drivability by the gate electric field and improves the S-factor of the select transistor at the same time.

Still further, a negative type resist 15 was used in filling silicon oxide film 11 in element isolation trench 2d between select gate electrodes SG. Thus, during lithographic exposure, the diffracted light is utilized to allow the edge of opening 15b of resist 15 to maintain its location immediately below select gate electrode SG and thereby allowing silicon oxide film 11 to be filled to the location immediately below the select gate electrode SG.

The gap between select gate electrodes SG was filled with silicon oxide film 11 which can be formed at relatively low temperatures as compared to an ordinary silicon oxide film. Thus, silicon oxide film 11 can be formed over resist 15 without affecting resist 15 and be etched back to the desired pattern.

The foregoing embodiments may be modified as follows.

Negative type resist film 15 may be replaced by a positive type resist.

Silicon oxide film 11 filling the gap between gate electrodes SG is formed so as to lie entirely across element isolation trench 2d located between gate electrodes SG. However, it is sufficient to form silicon oxide film 11 in the portion of element isolation insulation trench 2d located below gate electrode SG to prevent formation of silicon oxide film 12 into gate electrode MG side.

The silicon oxide film 14, serving as a sacrificial film which was only partially etched away so as to remain in element isolation insulation trench 2d, may be fully etched away. Further, silicon oxide film 14 formed based on polysilazane (PSZ) coating liquid may be made by other types of materials as long as the resulting film can be selectively etched after formation of gate electrodes MG and SG.

Polysilicon film 4 serving as the first electrode film and polysilicon films 6a and 6b serving as the second electrode film may each be replaced by an amorphous silicon film. The amorphous silicon film, however, may eventually be transformed to a polysilicon film as it goes through the manufacturing process flow.

Tungsten silicide film serving as silicide film 7 may be replaced by a silicide of material such as nickel (Ni), cobalt (Co), titanium (Ti), platinum (Pt), palladium (Pd), tantalum (Ta), and Molybdenum (Mo).

A dummy transistor may be provided between select gate transistor Trs1 and memory cell transistor Trm.

Foregoing embodiments were described through NAND flash memory application. Embodiments applied to other types of nonvolatile semiconductor storage device such as NOR flash memory and EEPROM also fall within the scope of the application.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a nonvolatile semiconductor storage device, comprising:
forming a gate insulating film and a first electrode film in the listed sequence above a semiconductor substrate;
forming an element isolation trench along a first direction into the first electrode film, the gate insulating film, and the semiconductor substrate to define an element region isolated in a second direction;
filling the element isolation trench with a sacrificial film;
forming an interelectrode insulating film, and a second electrode film in the listed sequence above the element region and the sacrificial film;
etching the second electrode film, the interelectrode insulating film, and the first electrode film along a second direction to form a plurality of first gate electrodes and a plurality of second gate electrodes such that the first gate electrodes are disposed in a first region, and the second gate electrodes are disposed in a second region adjacent to the first region,
selectively removing the sacrificial film in the element isolation trench after the formation of the first and the second gate electrodes; and
forming a resist, after the removal of the sacrificial film, and patterning the resist to define an opening in the first region;
forming a barrier insulating film, after patterning the resist, so as to at least cover an edge of the opening;
etching back the barrier insulating film to expose the resist film such that the barrier insulating film remains at least partially in the first region and thereafter removing the resist film;
forming a first insulating film, after removal of the resist film, across the first region, the second region, and the third region to form an unfilled gap in the element isolation trench located below the second region, the second region; and
forming a second insulating film above the first insulating film.

2. The method according to claim 1, wherein the resist comprises a negative type resist.

3. The method according to claim 2, wherein the opening defined in the resist includes a first edge located above the first gate electrode and a second edge located below the first gate electrode in the element isolation trench.

4. The method according to claim 3, wherein the barrier insulating film is formed along the upper surface, the first edge, and the second edge of the resist as well as along a sidewall of the first gate electrode located in the first region and along a bottom surface of the element isolation trench located in the first region.

5. The method according to claim 1, wherein the barrier insulating film comprises a silicon oxide film.

6. The method according to claim 5, wherein the silicon oxide film comprises a silicon oxide film formed at low temperatures.

7. The method according to claim 1, wherein the sacrificial film is selectively removed by wet etching using a hydrofluoric acid based wet etchant.

8. The method according to claim 1, wherein the first insulating film comprises a silicon oxide film formed under conditions providing poor step coverage.

9. The method according to claim 8, wherein the first insulating film located in the first region is etched back into a spacer-like shape before the formation of the second insulating film.

10. The method according to claim 1, wherein the second insulating film comprises a silicon oxide film.

11. The method according to claim 1, wherein the first gate electrode comprise a select gate electrode of a select transistor and the second gate electrode comprises a stacked gate structure of a memory cell transistor, the stacked gate structure including a floating gate electrode comprising the first electrode film and a control gate electrode comprising the second electrode film to thereby constitute a NAND flash memory.

12. A nonvolatile semiconductor storage device, comprising:
a semiconductor substrate;
an element isolation trench formed along a first direction into the semiconductor substrate;
an element region isolated in a second direction by the element isolation trench;
a plurality of first gate electrodes, and a plurality of second gate electrodes formed above the element region such that the first gate electrodes are disposed in a first region and the second gate electrodes are disposed in a second region adjacent to the first region, each of the first gate electrode and the second gate electrode including a gate insulating film, a first electrode film, an interelectrode insulating film and a second electrode film stacked in the listed sequence;
a barrier insulating film filled in the element isolation trench located in the first region;
a first insulating film formed across the first region and the second region to define an unfilled gap in the element isolation trench located below the second gate electrodes and a part of the first gate electrodes; and
a second insulating film formed above the first insulating film.

13. The device according to claim 12, wherein the barrier insulating film comprises a silicon oxide film.

14. The device according to claim 13, wherein the silicon oxide film comprises a low temperature silicon oxide film formed at low temperatures.

15. The device according to claim 12, wherein the first insulating film comprises a silicon oxide film formed under conditions providing poor step coverage.

16. The device according to claim 15, wherein the first insulating film located in the first region is etched back into a spacer-like shape.

17. The device according to claim 12, wherein the second insulating film comprises a silicon oxide film.

18. The device according to claim 12, wherein the first gate electrode comprise a select gate electrode of a select transistor and the second gate electrode comprises a stacked gate structure of a memory cell transistor, the stacked gate structure including a floating gate electrode comprising the first electrode film and a control gate electrode comprising the second electrode film to thereby constitute a NAND flash memory.

19. The device according to claim 12, wherein an edge of the barrier insulating film filling the element isolation trench located in the first region extends at least between a bottom surface of the element isolation trench and the underside of the first gate electrode.
